(19) United States
(12) Patent Application Publication
(10) Pub. No.: US 2011/0013785 A1
(43) Pub. Date: Jan. 20, 2011

(54) APPARATUS AND METHOD FOR CONTROLLING A PORTABLE TERMINAL

(75) Inventor: Min-Soo KIM, Gyeongsangbuk-do (KR)

Correspondence Address: Cha & Reiter, LLC, 17 Arcadian Avenue, Suite 208, Paramus, NJ, 07652, US

(73) Assignee: SAMSUNG ELECTRONICS CO., LTD., Gyeonggi-Do (KR)

(21) Appl. No.: 12/837,571

(22) Filed: Jul. 16, 2010

(30) Foreign Application Priority Data
Jul. 17, 2009 (KR) 10-2009-0065498

(51) Int. Cl. H03G 3/00

(52) U.S. Cl. 381/107

(57) ABSTRACT

A method for controlling a portable terminal includes confirming whether volume of sound input to microphones is a predetermined level or greater, confirming whether sound having volume of the predetermined level or greater has been input for a predetermined time period or more, confirming whether a pair of microphones to which sound having symmetrical volume has been input is present, among microphones to which sound having volume of the predetermined level or greater has been input for the predetermined time or more, and if so, confirming that scroll input by a user has been performed in an arrangement direction of the pair of microphones.

### CLAIM OF PRIORITY

This application claims the benefit under 35 U.S.C. §119(a) of a Korean Patent Application filed in the Korean Intellectual Property Office on Jul. 17, 2009 and assigned Serial No. 10-2009-0065498, the entire disclosure of which is hereby incorporated by reference.

### BACKGROUND OF THE INVENTION

1. Field of the Invention

The present invention relates generally to an apparatus and method for controlling a portable terminal, and more particularly, to an apparatus and method of controlling a portable terminal by sensing sound input to microphones.

2. Description of the Related Art

Generally, a portable terminal refers to a communication device capable of providing voice and data services while a user is roaming. Recently, various and useful functions are available in a portable terminal to meet demands in the age of digital convergence. For example, a user employs a portable terminal to use Audio On Demand (AOD) and Video On Demand (VOD) services or video calls to carry out conversations while watching each other's face, or download and play the game. Thus, the portable terminal is not limited only to the area of a voice call any more.

As the functions implemented in a portable terminal are diversified, users feel the need to control the portable terminal more quickly and conveniently. To this end, portable terminal manufacturers have provided a display of a touch screen type. The touch screen used in a portable terminal includes capacitive overlay, resistive overlay, surface acoustic wave, transmitter, and infrared beam types.

However, the touch screen may not be properly recognized the commands or may not function normally. For example, when a user touches the touch screen to control the portable terminal, a part of a display screen of a display may be unseen due to the user's finger or other means (e.g. a touch pen). As the control mechanisms of the portable terminal may be obstructed, it may be inconvenient when manipulating the screen during a display of content.

Accordingly, there is a need for controlling a portable terminal, which can easily control the portable terminal without additional keys, prevent recognition error or malfunction during a touch operation of a touch screen, and ensure a user's view during the touch operation.

### SUMMARY OF THE INVENTION

An aspect of the present invention is to address at least the above-mentioned problems and/or disadvantages and to provide at least the advantages described below. Accordingly, an aspect of the present invention provides a method for controlling a portable terminal without additional keys and without blocking a user's view of a display screen.

In accordance with an aspect of exemplary embodiments of the present invention, a method for controlling a portable terminal includes confirming whether volume of sound input to microphones is at a predetermined level or higher, confirming whether sound volume of the predetermined level or higher has been input for a predetermined time period or more, confirming whether a pair of microphones to which sound having symmetrical volume has been input is present, among microphones to which sound having volume of the predetermined level or higher has been input for the predetermined time period or more, and if so, confirming that a scroll input by a user has been performed in a specific direction between the pair of microphones based on the level of the detected sound volume.

In accordance with another aspect of exemplary embodiments of the present invention, an apparatus for controlling a portable terminal includes one or more microphones for receiving sound input from the exterior of the portable terminal, and a controller confirming whether volume of sound input to microphones is a predetermined level or higher, confirming whether detected sound volume has been input for a predetermined time period or more, confirming whether a pair of microphones to which sound having a symmetrical volume has been input is present, among microphones to which sound having volume of the predetermined level or higher has been input for the predetermined time period or more, and if so, confirming that a scroll input by a user has been performed in a particular direction between the pair of microphones based on the level of detected sound volume.

### BRIEF DESCRIPTION OF THE DRAWINGS

The above and other aspects, features and advantages of certain exemplary embodiments of the present invention will be more apparent from the following description taken in conjunction with the accompanying drawings, in which:

FIG. 1 is a block diagram of a portable terminal according to an exemplary embodiment of the present invention;

FIG. 2 is a flow chart illustrating a process for controlling a portable terminal through sound input to microphones according to an exemplary embodiment of the present invention;

FIG. 3 is a diagram illustrating an example of scroll input or tapping input in the process of FIG. 2;

FIGS. 4A and 4B are diagrams illustrating waveforms of sound input to a pair of microphones by scroll input in the process of FIG. 2; and

FIG. 5 is a diagram illustrating a waveform of sound input to a microphone by tapping input in the process of FIG. 2

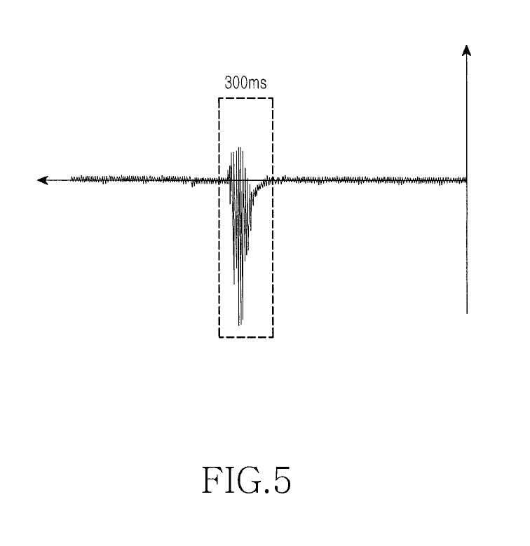

Throughout the drawings, the same drawing reference numerals will be understood to refer to the same elements, features and structures.

### DETAILED DESCRIPTION OF THE INVENTION

Reference will now be made in detail to the exemplary embodiments of the present invention with reference to the accompanying drawings. The following detailed description includes specific details in order to provide a thorough understanding of the present invention. However, it will be apparent to those skilled in the art that the present invention may be practiced without such specific details.

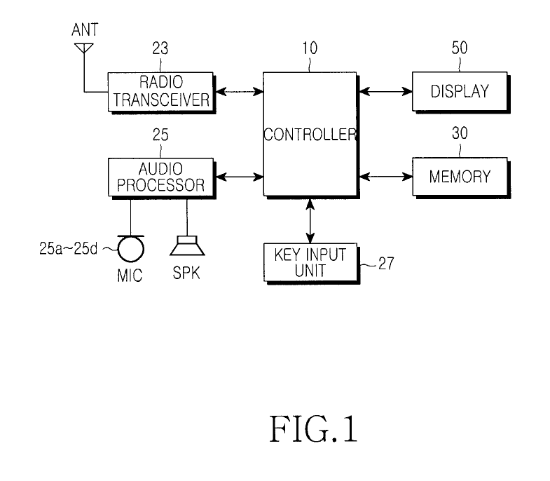

FIG. 1 is a block diagram of a portable terminal according to an exemplary embodiment of the present invention.

A key input unit 27 includes keys for inputting number, character information, and function keys for operating various functions.

A radio transceiver 23 performs a radio communication function of the portable terminal and includes a Radio Frequency (RF) unit and a modulator-demodulator (modem). The RF unit includes an RF transmitter for up-converting and amplifying a frequency of a transmitted signal and includes an RF receiver for low-noise amplifying a received signal and down-converting a frequency of the received signal. The modem includes a transmitter for encoding and modulating a signal to be transmitted and a receiver for demodulating and decoding a signal received from the RF unit.

An audio processor 25 may constitute a codec, including a data codec processing packet data and an audio codec processing audio signals such as voice and multimedia files. The audio processor 25 converts digital audio signals received from the modem into analog signals through the audio codec to reproduce the audio signals. The audio processor 25 also converts analog audio signals generated from microphones MIC into digital audio signals through the audio codec to transmit the converted audio signal to the modem. The codec may be independently provided or may be included in a controller 10.

The audio processor 25 may include one or more microphones. For the convenience of description and reduce redundancy, it is assumed that the audio processor 25 includes 4 microphones 25a to 25d. However, the number of microphones included in the audio processor 25 is not restricted thereto.

A memory 30 includes a Read Only Memory (ROM) and a Random Access Memory (RAM). The memory 30 may be comprised of a program memory and a data memory and may store programs for controlling an operation of the portable terminal and data for booting up the portable terminal.

The display 50 displays video signals and user data on a display screen or displays data relating to phone call. The display 50 may be comprised of a Liquid Crystal Display (LCD) or an Organic Light Emitting Diode (OLED). When constructing the LCD or OLED by a touch screen type, the display 50 may function as an input unit for controlling the portable terminal in conjunction with the key input unit 27.

The controller 10 controls the overall operation of the portable terminal. According to the exemplary embodiment of the present invention, the controller 10 senses sound input to the microphones to control the portable terminal accordingly, as explained hereinafter.

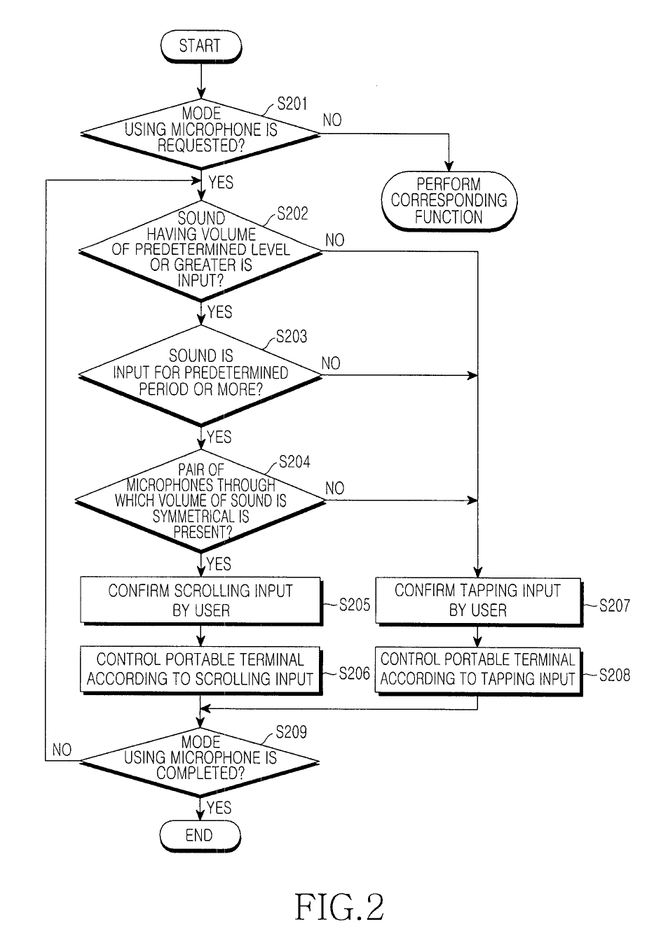

FIG. 2 is a flow chart illustrating a process for controlling a portable terminal through sound input to microphones according to an exemplary embodiment of the present invention.

Referring to FIG. 2, the controller 10 confirms whether a microphone mode is requested by a user in step S201. If it is requested, the controller 10 confirms whether sound having volume of a predetermined level or greater has been input to the microphones in step S202.

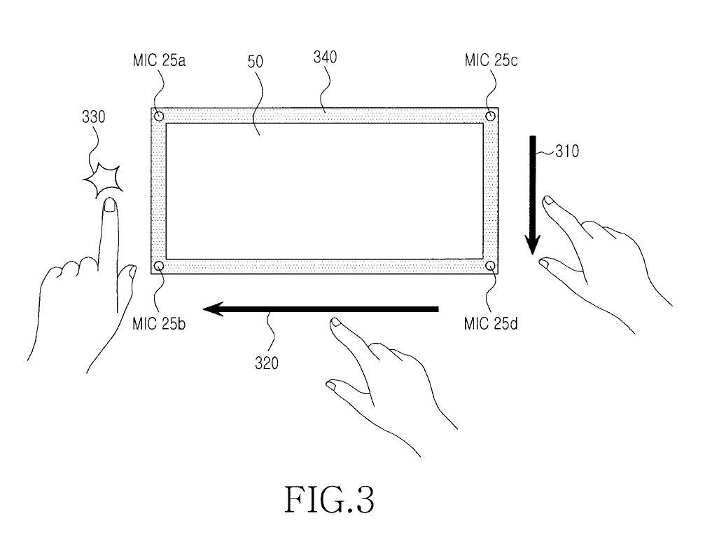

Referring to FIG. 3, it is seen that a user may drag his finger in downward direction on a partial surface 340 of a housing of a portable terminal, as indicated by a solid arrow 310, or drag his finger in leftward direction as indicated by a solid arrow 320. Namely, a user may drag a prescribed part of the surface 340 from the top to the bottom, based on the right side of a display screen of the display 50, as indicted by reference numeral 310, or from the right to the left, based on the lower side of the display screen of the display 50, as indicated by reference numeral 320. Through such a drag operation, sound is generated by friction between the surface and the user's finger. Note that the sound is generated by friction the finger and surface of the wall.

Accordingly, the controller 10 confirms whether the sound generated by a drag operation by a user has been input through the microphones 25a to 25d. To this end, the controller 10 confirms whether sound having volume of a predetermined level or higher has been input to the microphones 25a to 25d. This procedure is to distinguish sound input by a user from noise and prevents ambient noise from being recognized as the sound generated by a drag operation.

In this case, the controller 10 may check the sound generated by a drag operation performed on the display screen of the display 50 as in a touch screen type portable terminal. However, the drag operation directly on the display screen may cause a user not to be able to see a part of the display screen. It may be assumed that sound is generated by performing a drag operation on an object around the display screen, instead of the display screen. The object around the display screen may be the surface of a desk on which a portable terminal is placed.

Here, the sound (friction sound or friction noise) is generated by friction between the finger and the surface of a desk. Alternatively, the object around the display screen may be a bezel around the display screen, i.e. display bezel. So, user may see the display screen while making sound by dragging his finger on the display bezel.

Alternatively, a drag operation is performed on the partial surface 340 of the housing of the portable terminal around the display 50 within the range of not blocking user's view of the display screen. Further, a user may generate sound by dragging a prescribed surface using a means (e.g. a stylus pen or other objects) other than the user's finger. According to a modified exemplary embodiment of the present invention, the drag operation may be replaced by moving a means for generating sound in the air.

The predetermined level of volume may be set by portable terminal manufacturers and may be re-set by a user in view of an ambient noise level. Therefore, even if ambient noise occurs, a user can adaptively control the portable terminal through re-setting of a volume level that is distinguishable from noise that may interfere with the operation.

Referring back to FIG. 2, the controller 10 confirms whether sound having volume of a predetermined level or higher has been input for a predetermined time period or more in step S203.

In controlling the portable terminal through sound input to microphones according to the exemplary embodiment of the present invention, it is assumed that sound by a drag operation is scrolling input, and sound by a tapping operation is tapping input. If a user performs a drag operation, sound is generated for a predetermined time period (e.g. 300 ms) or more. If a user performs a tapping operation, sound is generated for a predetermined time period or less. Accordingly, sound input to the microphones may be distinguished between scrolling input and tapping input based on a predetermined time period.

If it is confirmed that sound having volume of a predetermined level or higher has been input for a predetermined time period or more in step S203, the controller 10 confirms whether a pair of microphones to which sound having a symmetrical volume has been input is present in step S204. If such microphones are present, the controller 10 judges that scroll input by a user has been performed in step S205.

Although the portable terminal may be controlled by sound having volume of a predetermined level or higher for a predetermined time period as scrolling input by a user, sound is confirmed again with respect to a pair of microphones in order to prevent the portable terminal from being controlled by external noise. That is, the controller 10 confirms, through two microphones, whether sound has been input for a predetermined time period or more with volume of a predetermined level or higher

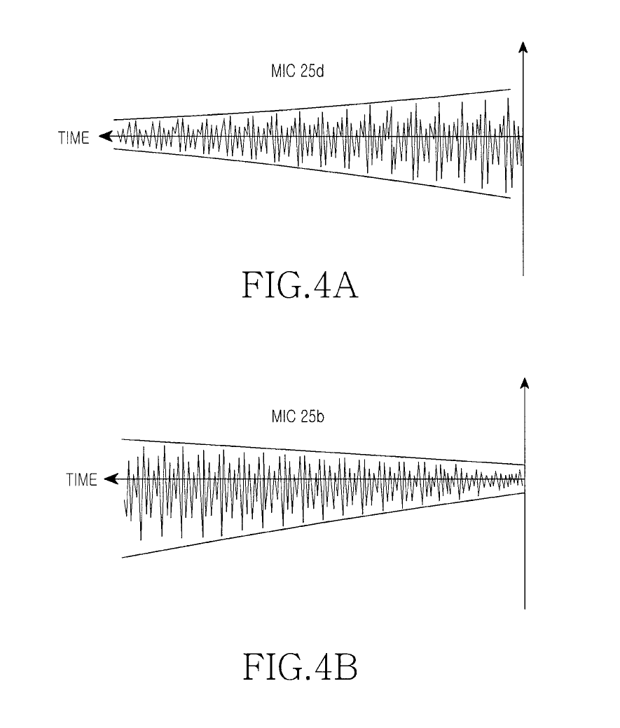

For example, referring back to FIG. 3, if a user drags a prescribed part of the partial surface 340 of the portable terminal from the right to the left, based on the lower side of the display screen, as indicated by reference numeral 320, sound input to the microphone 25d gradually changes from high volume to low volume as a user's finger moves from the right to the left (e.g. as a users finger becomes away from the microphone 25d), as shown in the waveform of FIG. 4A. On the contrary, sound input to the microphone 25b gradually changes from low volume to high volume as a user's finger moves from the right to the left (e.g. as a user's finger becomes near to the microphone 25b), as shown in the waveform of FIG. 4B. Referring to FIGS. 4A and 4B, sound input to the microphone 25d and sound input to the microphone 25b show a symmetrical form as time elapses according to a drag operation by a user.

Accordingly, if sound having volume of a predetermined level or higher has been input for a predetermined time period or more, the controller 10 confirms whether there is a pair of microphones to which sound having a symmetrical volume has been input based on time, thereby accurately checking scrolling input distinguished from external noise. The two drag function can be performed separately or together. In FIG. 3, 310 describes a situation in which a drag action happens in a vertical direction and 320 describes a situation in which a drag action happens in a horizontal direction.]

If such a pair of microphones is confirmed, the controller 10 can identify a direction of scroll input according to a drag operation by a user. Namely, if the presence of the microphones is confirmed, the controller 10 confirms the direction of scroll input by confirming a variation of sound input to at least one of the two microphones.

For example, the controller 10 may confirm sound input to the microphones 25b and 25d in the left and right of the surface below the display screen. If the controller 10 confirms that sound input to the microphone 25d is as shown in FIG. 4A, the controller 10 judges that scroll input by a user is performed from the right to the left of the surface below the display screen.

In accordance with variation of exemplary embodiments of the present invention, the controller 10 may controls to display locations of the checked microphones after checking the microphones to which sound of volume of the predetermined level or greater has been input. Therefore, user may recognize locations of the checked microphones through the display 50.

In accordance with variation of exemplary embodiments of the present invention, if user may select at least one of the location displayed microphones when the locations of the checked microphones are displayed, the controller 10 may control to confirm whether sound input through the selected microphone (or microphones) has been maintained for a predetermined time period or more.

Next, the controller 10 controls the portable terminal according to the confirmed scroll input in step S206.

Thus, if it is confirmed that scroll input by a user is performed and the direction of the scroll input is checked, the controller 10 may control the portable terminal according to the scroll input.

Although examples of the control of the portable terminal according to the scroll input cover a wide range, a few other examples are as follows. If a user drags a prescribed surface while a photo is displayed, the controller 10 may display previous or next photos of the displayed photo according to confirmed scroll input. Then the user may view displayed photos without blocking user's sight.

Referring back to FIG. 2, if it is confirmed that sound having volume of a predetermined level or greater has not been input for a predetermined time period or more in step S203, the controller 10 judges that tapping input by a user has been performed in step S207 and controls the portable terminal according to the confirmed tapping input in step S208.

As described above, if sound having volume of a predetermined level or greater has not been input for a predetermined time period or more, it is confirmed that tapping input by a user has been performed. For example, if a user taps a part around the microphone 25a or 25b using the user's finger as indicated by reference numeral 330 in FIG. 3, sound having volume of a predetermined level or more has been input to the microphone 25a or 25b for a predetermined time period (e.g. 300 ms) or less and thus the controller 10 judges that tapping input by a user has been performed. In this case, the controller 10 confirms that the tapping input has been performed in the left of the display screen by checking the detection of sound location of the microphone 25a or 25b based on the display screen. Next, the controller 10 controls the portable terminal according to the tapping input in the left of the display screen. An example of the control of the portable terminal according to the tapping input may be an operation of magnifying or reducing a displayed photo while the photo is displayed.

The controller 10 performs steps S202 to S208 until the microphone mode is ended in step S202 to control the portable terminal according to the scroll input or the tapping input.

While the exemplary embodiment of the present invention illustrates 4 microphones 25a to 25d as shown in FIG. 3, the number and location of microphones may be changed according to modifications of the embodiment of the present invention. For example, only three microphones 25b, 25c and 25d without the microphone 25a may be arranged to sense vertical/horizontal scroll input and tapping input.

The above-described methods according to the present invention can be realized in hardware or as software or computer code that can be stored in a recording medium such as a CD ROM, an RAM, a floppy disk, a hard disk, or a magneto-optical disk or downloaded over a network, so that the methods described herein can be executed by such software using a general purpose computer, or a special processor or in programmable or dedicated hardware, such as an ASIC or FPGA. As would be understood in the art, the computer, the processor or the programmable hardware include memory components, e.g., RAM, ROM, Flash, etc. that may store or receive software or computer code that when accessed and executed by the computer, processor or hardware implement the processing methods described herein.

As is apparent from the foregoing, a portable terminal can be controlled without additional key input and the portable terminal can be controlled without blocking a display screen.

Although the exemplary embodiments of the present invention have been disclosed for illustrative purposes, various modifications, additions and substitutions are possible, without departing from the scope and spirit of the invention as disclosed in the accompanying claims. Accordingly, the scope of the present invention should not be limited to the description of the embodiment, but defined by the accompanying claims and equivalents thereof.

What is claimed is:

1. A method for controlling a portable terminal having a plurality of microphones, comprising:
confirming whether volume of sound input to the at least one of microphones is a predetermined level or greater;
if so, confirming whether the volume of sound input has been input for a predetermined time period or more;
if so, confirming whether a pair of microphones to which sound having a symmetrical volume pattern has been input is present; and
if so, confirming that a scroll input by a user has been performed in a specific direction based on the level of the sound input detected by the pair of microphones.

2. The method of claim 1, further comprising controlling the portable terminal according to the confirmed scroll input.

3. The method of claim 1, further comprising checking the microphones to which sound of volume of the predetermined level or greater has been input and displaying locations of the checked microphones.

4. The method of claim 3, further comprising confirming whether sound input through a microphone selected by a user among the microphones of which locations are displayed has been maintained for a predetermined time period or more.

5. The method of claim 1, further comprising:
if sound having volume of the predetermined level or greater has been input for less than the predetermined time period, checking a location of a microphone to which sound having volume of the predetermined level or greater has been input for less than the predetermined time period; and
if so, confirming that tapping input by a user has been performed.

6. The method of claim 5, wherein the tapping input has been performed at the confirmed location of the microphone.

7. The method of claim 5, further comprising controlling the portable terminal according to the tapping input.

8. An apparatus for controlling a portable terminal, comprising:
one or more microphones for receiving sound input; and
a controller confirming whether volume of the sound input to microphones is a predetermined level or greater, confirming whether the sound input equal or greater than the predetermined level last more than a predetermined time period or more, if so, confirming whether a pair of microphones to which sound having symmetrical volume has been input is present, and if so, confirming that a scroll input by a user has been performed in a specific direction between the pair of microphones.

9. The apparatus of claim 8, wherein the controller controls the portable terminal according to the confirmed scroll input.

10. The apparatus of claim 8, wherein the controller checks microphones to which sound of volume of the predetermined level or greater has been input and controls a display to display locations of the checked microphones.

11. The apparatus of claim 10, wherein the controller confirms whether sound input through a microphone selected by a user among the microphones of locations are displayed has been maintained for a predetermined time period or more.

12. The apparatus of claim 8, wherein if the sound input is less than the predetermined time period, the controller confirms that a tapping input by a user has been performed.

13. The apparatus of claim 12, wherein the controller confirms that the tapping input has been performed at a location of a microphone where the sound level is less than the predetermined time period.

14. The apparatus of claim 12, wherein the controller controls the portable terminal according to the tapping input.
